(19) United States
(12) Patent Application Publication
(10) Pub. No.: US 2015/0060115 A1
(43) Pub. Date: Mar. 5, 2015

(54) COPPER CLAD LAMINATE FOR PRINTED CIRCUIT BOARD AND MANUFACTURING METHOD THEREOF

(71) Applicant: SAMSUNG ELECTRO-MECHANICS CO., LTD., Suwon (KR)

(72) Inventors: Sa Yong Lee, Suwon (KR); Jin Seok Moon, Suwon (KR); Keun Yong Lee, Suwon (KR)

(73) Assignee: SAMSUNG ELECTRO-MECHANICS CO., LTD., Suwon (KR)

(21) Appl. No.: 14/079,236

(22) Filed: Nov. 13, 2013

(30) Foreign Application Priority Data
Aug. 28, 2013 (KR) 10-2013-0102631

(51) Int. Cl. H05K 1/03; H05K 3/20; H05K 1/09; H05K 1/05

(52) U.S. Cl. CPC H05K 1/036; H05K 1/0306; H05K 1/038; H05K 1/056; H05K 3/202; H05K 1/09; H05K 2201/0358
USPC 174/255; 428/426; 428/221; 156/60

(57) ABSTRACT

Disclosed herein are a copper clad laminate for a printed circuit board, in which a composite having a glass fibers formed on both sides of a prepreg is disposed between a resin layer of a first resin-coated copper foil (RCC) and a resin layer of a second resin-coated copper foil and having a structure in which the resin layers are symmetric or asymmetric based on the composite, and a manufacturing method thereof. A thickness of the copper clad laminate may be manufactured at the desired thickness or the thickness may be uniformly maintained, such that stabilization of thickness quality may be implemented, the adhesion between the copper foil and the resin may be improved, and warpage may be adjusted when laminating substrates having different upper and lower thermal expansion coefficients.

### CROSS REFERENCE TO RELATED APPLICATION

This application claims the benefit of Korean Patent Application No. 10-2013-0102631, filed on Aug. 28, 2013, entitled “Copper Clad Laminate for Printed Circuit Board and Manufacturing Method of Thereof”, which is hereby incorporated by reference in its entirety into this application.

### BACKGROUND OF THE INVENTION

1. Technical Field

The present invention relates to a copper clad laminate for a printed circuit board and a manufacturing method thereof.

2. Description of the Related Art

In accordance with an advancement of an electronic device, a printed circuit board has gradually become light, thin, and small. In order to satisfy these demands, the printed circuit board has become more complex with higher density wiring. As such, electrical, thermal, and mechanical characteristics required from the printed circuit board are deemed to be important factors.

The printed circuit board has a configuration mainly comprised of copper serving as a circuit wire and polymer serving as interlayer insulator. The polymer constructing an insulating layer is required with several characteristics such as a thermal expansion coefficient, a glass transition temperature, uniformity of thickness, and the like as compared to the copper, and needs to be manufactured at a thinner insulating thickness.

A manufacturing method of a copper clad laminate (CCL) according to the prior art is as follows. First, a varnish for an insulating layer is mixed in a tank and then put into an impregnant vessel, and a glass fabric having a thin cloth shape is immersed in the impregnant vessel to coat the glass fabric with the varnish and the thickness of the coating is then uniformly adjusted. Next, this is transported to a drying stage and then is dried by hot-air or ultraviolet (UV) at the drying stage, thereby manufacturing a prepreg. Copper foils are each laminated on both surfaces of the prepreg manufactured as described above, thereby manufacturing a copper clad laminate.

Meanwhile, as the circuit board becomes thin, the circuit board has unstable thickness quality, such that characteristics of the thermal expansion coefficient, dielectric constant, dielectric loss, and the like may be degraded and a warpage phenomenon and signal transmission error in a high frequency region may be caused at the time of mounting components. Particularly, the manufacturing of the copper clad laminate according to the prior art as mentioned above may have a limitation in implementing the thinness of the copper clad laminate, may not constantly keep the thickness, and may not manufacture an asymmetric prepreg or copper clad laminate.

### SUMMARY OF THE INVENTION

Therefore, according to the present invention, the above-mentioned problems may be solved by a copper clad laminate formed by disposing a composite between a resin layer of a first resin-coated copper foil (RCC) and a resin layer of a second RCC using a resin composition having excellent heat-resisting property, and the present invention has been completed based on the above-mentioned content.

The present invention has been made in an effort to provide a copper clad laminate for a printed circuit board having a structure in which the resin layer of the first RCC and the resin layer of the second RCC are symmetric or asymmetric based on the composite.

Further, the present invention has been made in an effort to provide a manufacturing method of a copper clad laminate for a printed circuit board capable of manufacturing a thickness of the copper clad laminate for a printed circuit board at a desired thickness or uniformly maintaining the thickness, improving adhesion between copper foil and resin, and having the thickness of both sides which are symmetric or asymmetric based on the composite of the copper clad laminate.

Further, the present invention has been made in an effort to provide a printed circuit board applied by forming a circuit pattern on the copper foil of the copper clad laminate.

According to a preferred embodiment of the present invention, there is provided a copper clad laminate for a printed circuit board, in which a composite having a glass fibers formed on both sides of a prepreg is disposed between a resin layer of a first resin-coated copper foil (a first RCC) and a resin layer of a second resin-coated copper foil (a second RCC) and having a structure in which the resin layers are symmetric or asymmetric based on the composite.

The resin layers of the first RCC and the second RCC may have the same thickness or different thickness, the same composition or different composition, or the same kind and content or different kind and content of inorganic filler included in the composition.

The composite may be formed by further including at least one other prepreg between the prepreg and the glass fiber and laminating the prepreg, the at least one other prepreg, and the glass fiber.

The copper clad laminate may further include an insulator having the glass fiber formed on one side of the prepreg between the first RCC and the composite, between the second RCC and the composite, or both.

The glass fiber formed on one side of the insulator may contact the resin layers of the first RCC and the second RCC and include at least one insulator.

The glass fibers formed on both sides of the composite may be the same kind or different kinds.

The glass fiber may be at least one selected from a group consisting of E-glass, T-glass, S-glass, U-glass, quartz fiber textile, and aramid fiber textile.

According to another preferred embodiment of the present invention, there is provided a manufacturing method of a copper clad laminate for a printed circuit board, the manufacturing method including: providing a first RCC and a second RCC; forming a copper clad laminate by laminating and pressurizing a composite having glass fibers formed on both sides of a prepreg between a resin layer of the first RCC and a resin layer of the second RCC; and hardening the copper clad laminate.

The resin layers of the first RCC and the second RCC may have the same thickness or different thickness, the same composition or different composition, or the same kind and content or different kind and content of inorganic filler included in the composition.

The forming of the copper clad laminating may include laminating an insulator having the glass fiber formed on one side of the prepreg between the first RCC and the composite, between the second RCC and the composite, or both.

The glass fiber formed on one side of the insulator may be laminated so as to be in contact with the resin layers of the first RCC and the second RCC, and in the laminating of the insulator, at least one insulator is laminated.

The glass fibers formed on both sides of the composite may be the same kind or different kinds.

The glass fiber may be at least one selected from a group consisting of E-glass, T-glass, S-glass, U-glass, quartz fiber textile, and aramid fiber textile.

The pressuring may be performed by roll pressurization.

According to still another preferred embodiment of the present invention, there is provided a printed circuit board manufactured by forming a circuit pattern on a copper foil of the copper clad laminate as described above.

### BRIEF DESCRIPTION OF THE DRAWINGS

The above and other objects, features and advantages of the present invention will be more clearly understood from the following detailed description taken in conjunction with the accompanying drawings, in which:

FIG. 1A is a state view showing a laminating structure of a copper clad laminate having a composite disposed between a resin layer of a first RCC and a resin layer of a second RCC according to a representative embodiment of the present invention;

FIG. 1B is a cross-sectional view of the copper clad laminate manufactured according to the representative embodiment of the present invention;

FIG. 2A is a state view showing a laminating structure of a copper clad laminate having a composite and an insulator disposed between a resin layer of a first RCC and a resin layer of a second RCC according to another preferred embodiment of the present invention; and

FIG. 2B is a cross-sectional view of the copper clad laminate manufactured according to another preferred embodiment of the present invention.

### DESCRIPTION OF THE PREFERRED EMBODIMENTS

Before the present invention is described in more detail, it must be noted that the terms and words used in the present specification and claims should not be interpreted as being limited to typical meanings or dictionary definitions, but should be interpreted as having meanings and concepts relevant to the technical scope of the present invention based on the rule according to which an inventor can appropriately define a concept implied by a term to best describe the method he or she knows for carrying out the invention. Further, the embodiments of the present invention are merely illustrative, and are not to be construed to limit the scope of the present invention, and thus there may be a variety of equivalents and modifications able to substitute for them at the point of time of the present application.

In the following description, it is to be noted that embodiments of the present invention are described in detail so that the present invention may be easily performed by those skilled in the art, and also that, when known techniques related to the present invention may make the gist of the present invention unclear, a detailed description thereof will be omitted.

Copper Clad Laminate (CCL)

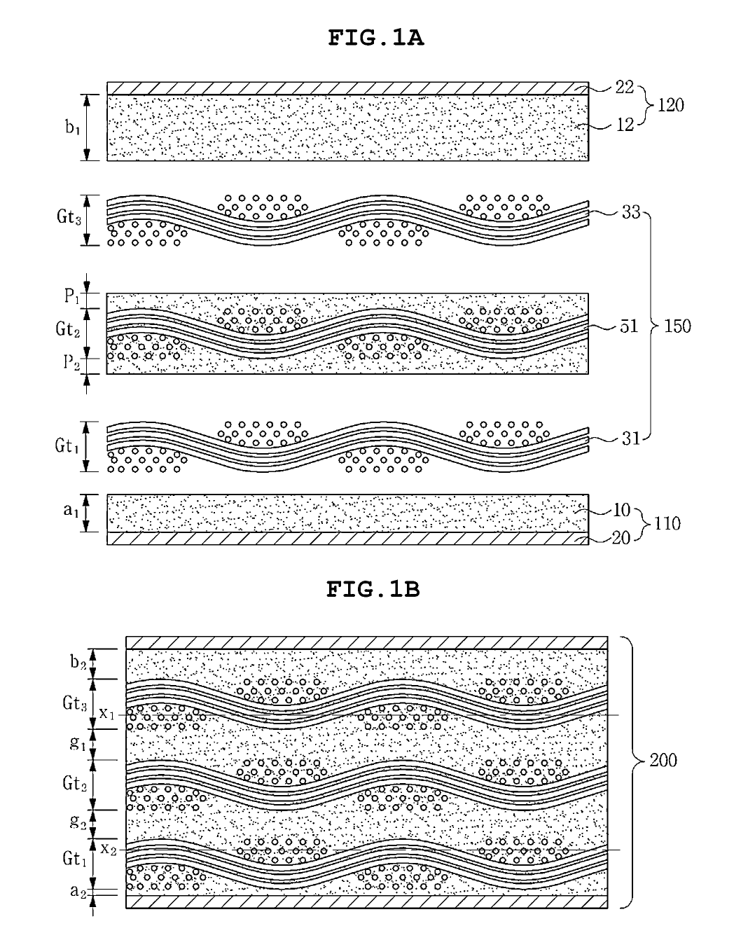

FIG. 1A is a state view showing a laminating structure of a copper clad laminate having a composite disposed between a resin layer of a first RCC and a resin layer of a second RCC according to a representative embodiment of the present invention. Referring to FIG. 1A, a composite 150 having glass fibers formed on both sides of a prepreg is disposed between a first resin layer 10 and a second resin layer 12 formed in a first resin-coated copper foil (a first RCC) 110 and a second resin-coated copper foil (a second RCC) 120, respectively, such that a copper clad laminate 200 having a structure in which the first resin layer 10 and the second layer 12 are symmetric or asymmetric based on the composite 150 may be formed.

FIG. 1B is a cross-sectional view of the copper clad laminate manufactured according to the representative embodiment of the present invention. Referring to FIG. 1B, FIG. 1B shows the cross-sectional view of the copper clad laminate 200 in which the first RCC 110, the composite 150 having the glass fibers formed on both sides of the prepreg, and the second RCC 120 are sequentially laminated, where a boundary surface between the second resin layer 12 of the second RCC 120 and the prepreg of the composite 150 is denoted by an alternated long and short dash line of x₁ and a boundary surface between the first resin layer 10 of the first RCC 110 and the prepreg of the composite 150 is denoted by an alternated long and short dash line of x₂. x₁ and x₂ denoted by the alternated long and short dash lines may be upper and lower symmetric or asymmetric depending on thicknesses of the first resin layer 10 and the second resin layer 12. The glass fibers formed on both sides of the composite may be the same kind or different kinds according to the situation.

The copper clad laminate formed according to the representative embodiment of the present invention may have a low thermal expansion coefficient to implement thermal stability and may improve mechanical modulus to selectively adjust warpage, as compared to the copper clad laminate completed by laminating a plurality of prepregs and forming the copper foils on both surfaces according to the prior art. Referring to FIGS. 1A and 1B, in FIG. 1A, a thickness of the first resin layer 10 is denoted by a₁, a thickness of the second resin layer 12 is denoted by b₁, and thicknesses of regions configured by only the resin on upper and lower portion of a prepreg 51 in included in the composite are denoted by p₁ and p₂, respectively. In addition, the glass fiber of the prepreg in the composite is denoted by Gt₂ and the glass fibers formed on both sides of the prepreg are denoted by Gt₁ and Gt₂, respectively. When laminating and pressurizing the first RCC, the composite, and the second RCC configured as shown in FIG. 1A, the copper clad laminate 200 as shown in FIG. 1B is formed. In the copper clad laminate 200, the thickness of the first resin layer and the thickness of the second resin layer are denoted by a₂ and b₂, respectively, and since the resin is permeated into the glass fibers Gt₁ and Gt₂ formed on both sides of the composite, the thickness of a₂ becomes relatively thinner than a₁ and the thickness of b₂ also becomes thinner than b₁. In addition, a thickness of a region configured by only the resin present between the glass fibers Gt₁ and Gt₂ of the copper clad laminate 200 is denoted by g₂ and a thickness of a region configured by only the resin present between the glass fibers Gt₂ and Gt₃ is denoted by g₁. Here, a thickness summing the thicknesses of a₂ and g₂ may be formed to be thinner than a thickness summing the thicknesses of a₁ and p₂ and a thickness summing the thicknesses of b₂ and g₁ may be formed to be thinner than a thickness summing the thicknesses of b₁ and p₁. In addition, the glass fibers Gt₁, Gt₂, and Gt₃ may be the same kind or different kinds. Therefore, the regions configured by only the resin between the glass fibers Gt₁ and Gt₂, between the glass fibers Gt₂ and Gt₃, between first copper foil layer and the glass fiber Gt₁, and between a second copper foil layer and the glass fiber Gt₃ are decreased, such that resin content is decreased. Thereby, as the resin content is decreased, the mechanical modulus tends to follow a structure body. Since the mechanical modulus of the structure body is generally higher than the resin, the copper clad laminate may have a low thermal expansion coefficient to implement thermal stability and may improve the mechanical modulus to selectively adjust the warpage.

The first resin layer and the second resin layer may have the same thickness or different thickness, the same composition or different composition, or the same kind and content or different kind and content of inorganic filler included in the composition. The copper clad laminate manufactured by the above-mentioned configuration may manufacture the thicknesses of the first resin layer and the second resin layer at the desired thickness or uniformly maintain the thickness, thereby making it possible to implement the stabilization of the thickness quality. In addition, while the copper clad laminate according to the prior art is manufactured by laminating and pressurizing the prepreg in a B-stage state and the copper foil, the copper clad laminate according to the present invention manufactured by applying the RCC including a resin layer which is not hardened may improve adhesion between the copper foil layer and the resin layer. Further, the copper clad laminate according to the representative embodiment of the present invention manufactured by forming the resin layers to be symmetric or asymmetric based on the composite artificially adjusts thermal expansion coefficients of upper and lower portions thereof, such that the warpage may be selectively adjusted depending on a remaining copper ratio of the copper foil when forming a pattern on the first copper foil layer and the second copper foil layer formed the upper and lower portions. For example, in the case in which the upper portion of the copper clad laminate has a high remaining copper ratio and the lower portion thereof has a low remaining copper ratio, the thickness and the composition of the resin layer of the RCC formed on the upper and lower portions and the kind and content of the inorganic filler included in the composition are artificially adjusted, thereby making it possible to selectively prevent the warpage.

As the composition used in the first resin layer and the second resin layer according to the preferred embodiment of the present invention, composition having resistant property against a pressure and heat generated from subsequent laminating and pressurizing operations may be appropriately used. The composition having the above-mentioned heat-resisting property may include an epoxy resin, polyester amide-based liquid crystal oligomer, silica inorganic filler, and solvent. Particularly, according to the present invention, mixtures denoted by the following Chemical Formulas 1 and 2 are suitable for the polyester amide-based liquid crystal oligomer and the epoxy resin, respectively, in view of the heat-resisting property and dimension stability. In addition, as the solvent, 2-methoxy ethanol, acetone, methyl ethyl ketone, cyclohexanone, ethyl acetate, butyl acetate, cellosolve acetate, propylene glycol monomethyl ether acetate, ethylene glycol monobutyl ether acetate, cellosolve, butyl cellosolve, carbitol, butyl carbitol, xylene, dimethyl formamide, and dimethyl acetamide may be used in consideration of solubility and miscibility of the resins and other additives used in the present invention, but the solvent is not limited thereto.

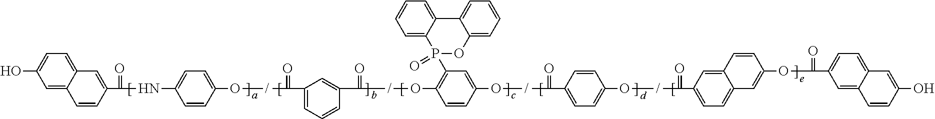

Here, number average molecular weight of the polyester amide-based liquid crystal oligomer denoted by the Chemical Formula 1 is 3500 to 5000.

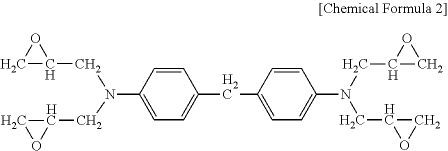 [SMILES: c1cc(N(CC2CO2)CC2CO2)ccc1Cc1ccc(N(CC2CO2)CC2CO2)cc1]

The inorganic fillers used in the present invention may be at least one selected from a group consisting of silica (SiO₂), talc, barium sulfate (BaSO₄), Barium titanate (BaTiO₃), alumina (Al₂O₃), clay, magnesium carbonate (MgCO₃), calcium carbonate (CaCO₃), aluminum hydroxide (Al(OH)₃), and silicate, but are particularly limited. In addition, the inorganic filler may be solely added to the composition, but may be added together with a silane coupling agent or a dispersant in order to improve dispersibility and binding force between the resins.

The copper clad laminate according to the representative embodiment of the present invention may be formed by laminating to further include at least one other prepreg between the prepreg of the composite and the glass fiber.

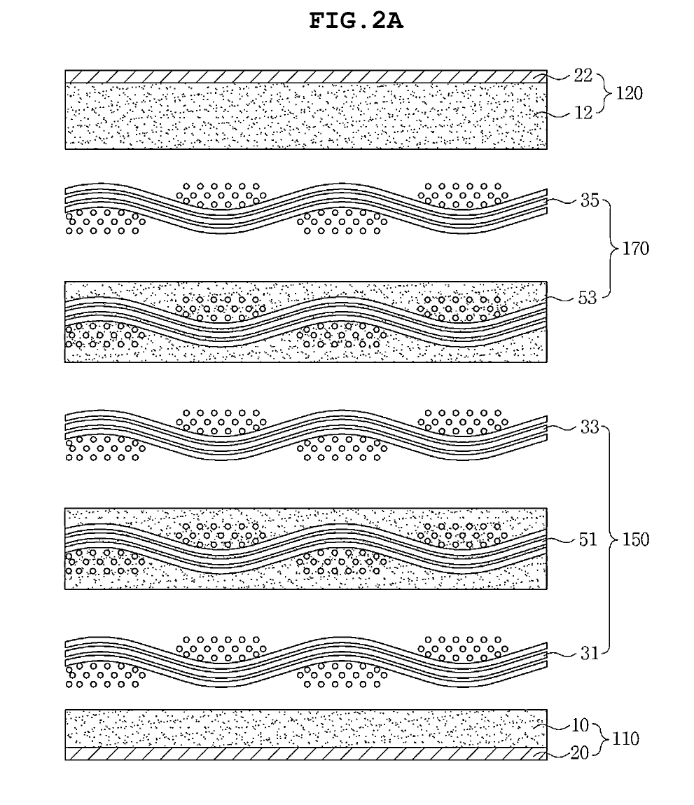

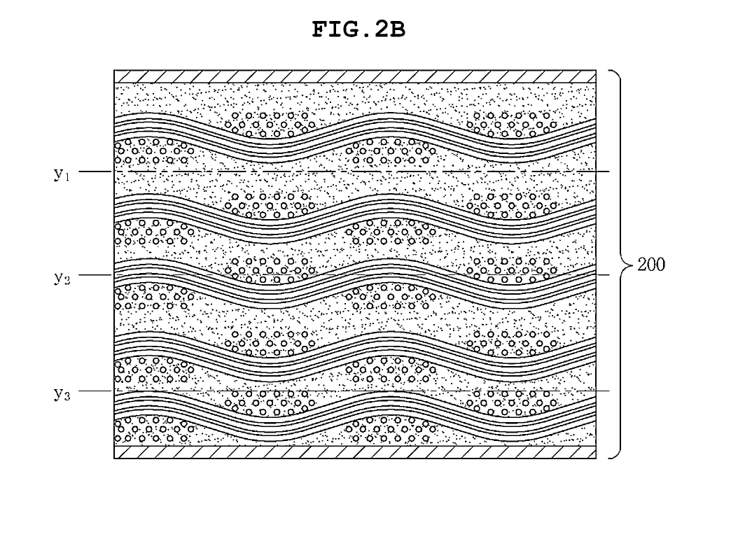

FIG. 2A is a state view showing a laminating structure of a copper clad laminate having a composite and an insulator disposed between a resin layer of a first RCC and a resin layer of a second RCC according to another preferred embodiment of the present invention. Referring to FIG. 2A, the composite 150 having the glass fibers formed on both sides of the prepreg is disposed between the first resin layer 10 and the second resin 12 formed in the first RCC 110 and the second RCC 120, respectively, and an insulator 170 having glass fiber formed on one side of the prepreg is disposed between the first RCC 100 and the composite 150 or between the second RCC 120 and the composite 150, such that a copper clad laminate 200 having upper and lower symmetric or asymmetric structure may be formed. The glass fiber formed on one side of the insulator 170 contacts the respective resin layers 10 and 12 of the first RCC 110 and the second RCC 120, and the copper clad laminate 200 may be formed by including at least one insulator 170.

FIG. 2B is a cross-sectional view of the copper clad laminate manufactured according to another preferred embodiment of the present invention. Referring to FIG. 2B, FIG. 2B shows the cross-sectional view of the copper clad laminate 200 in which, the first RCC 110, the composite 150 having the glass fibers formed on both sides of the prepreg, the insulator 170 having the glass fiber formed on one side of the prepreg, and the second RCC 120 are sequentially laminated, where a boundary surface between the second resin layer 12 of the second RCC 120 and the prepreg of the composite 150 is denoted by an alternated long and short dash line of y₁, a boundary surface between the prepreg of the insulator 170 and the prepreg of the composite 150 is denoted by an alternated long and short dash line of y₂, and a boundary surface between the first resin layer 10 of the first RCC 110 and the prepreg of the composite 150 is denoted by an alternated long and short dash line of y₃. y₁, y₂, and y₃ denoted by the alternated long and short dash lines may be upper and lower symmetric or asymmetric depending on thicknesses of the first resin layer and the second resin layer. The glass fibers formed on both sides of the composite may be the same kind or different kinds according to the situation.

In addition, also in the copper clad laminate 200 formed as shown in FIG. 2B, the regions configured by only the resin between the respective glass fibers and between a first copper foil layer and the glass fiber, and between a second copper foil layer and the glass fiber are decreased, such that resin content is decreased. Thereby, as the resin content is decreased, the mechanical modulus tends to follow a structure body. Since the mechanical modulus of the structure body is generally higher than the resin, the copper clad laminate may have a low thermal expansion coefficient to implement thermal stability and may improve the mechanical modulus to selectively adjust the warpage. The selective adjustment of the warpage may be artificially adjusted by differently applying the kinds of respective glass fibers present in the copper clad laminate.

The glass fiber used in the copper clad laminate formed according to the representative embodiment of the present invention may be at least one selected from a group consisting of E-glass, T-glass, S-glass, U-glass, quartz fiber textile, and aramid fiber textile. A standard of the glass fiber is according to ASTM D4422A and characteristics of a thickness and a thermal expansion coefficient may be different depending on the products.

Manufacturing Method of Copper Clad Laminate

The copper clad laminate for the printed circuit board according to the representative embodiment of the present invention may be manufactured by the manufacturing method including providing a first RCC and a second RCC, forming a copper clad laminate by laminating and pressurizing a composite having a glass fibers formed on both sides of a prepreg between a resin layer of the first RCC and a resin layer of the second RCC, and hardening the copper clad laminate. The resin layer of the first RCC and the resin layer of the second RCC may have the same thickness or different thickness, the same composition or different composition, or the same kind and content or different kind and content of inorganic filler included in the composition.

The forming of the copper clad laminate may further include laminating an insulator having the glass fiber formed on one side of the prepreg between the first RCC and the composite, between the second RCC and the composite, or both. The glass fiber formed on one side of the insulator is laminated so as to contact the resin layers of the first RCC and the second RCC, and in the laminating of the insulator, at least one insulator may be laminated. The glass fibers formed on both sides of the composite may be the same kind or different kinds according to the situation.

The glass fiber used in the copper clad laminate formed according to the representative embodiment of the present invention may be at least one selected from a group consisting of E-glass, T-glass, S-glass, U-glass, quartz fiber textile, and aramid fiber textile. A standard of the glass fiber is according to ASTM D4422A and characteristics of a thickness and a thermal expansion coefficient may be different depending on products.

The prepreg for the printed circuit board typically includes the glass fiber. This is to prevent the resin layer from being separated from a copper foil layer by heat generated at the time of an operation of a circuit since a resin used as an insulating composition and a copper foil which is metallic component have a significant difference in a thermal expansion coefficient thereof.

The laminating and pressurizing of the copper clad laminate according to the representative embodiment of the present invention, which is a process for coupling the first RCC, the second RCC, and the composite having the glass fibers formed on both sides of the prepreg or the composite having the glass fibers formed on both sides of the prepreg and at least one insulator having the glass fiber formed on one side of the prepreg disposed between the resin layer of the first RCC and the resin layer of the second RCC to one another, may be performed by disposing the composite or the composite and the insulator between the resin layer of the first RCC and the resin layer of the second RCC as mentioned above and then applying pressure from both directions. In this case, the pressure may be applied by a role pressurization scheme using two cylindrical pressurization roles in a direction facing each other.

The copper clad laminate manufactured according to the representative embodiment of the present invention has a circuit pattern formed on upper and lower copper foils thereof, such that the printed circuit board may be manufactured by a process of laminating an additive substrate.

Hereinafter, the present invention will be described in more detail through examples and comparative examples but the scope of the present invention is not limited thereto.

### Manufacturing of Resin-Coated Copper Foil (RCC)

### Manufacturing Example

4-aminophenol of 218.26 g (2.0 mol), isophthalic acid of 415.33 g (2.5 mol), 4-hydroxybenzoic acid of 276.24 g (2.0 mol), 6-hydroxy-2-naphthoic acid of 282.27 g (1.5 mol), DOPO-HQ of 648.54 g (2.0 mol), acetic anhydride of 1531.35 g (15.0 mol) were added in a glass reactor of 20 L. After sufficiently substituting nitrogen gas in the interior of the reactor, a temperature in the reactor was increased to about 230° C. under a flowing the nitrogen gas and was refluxed for about 4 hours while maintaining the temperature in the reactor at the 230° C. Next, 6-hydroxy-2-naphthoic acid of 188.18 g (1.0 mol) for capping an end was additionally added and acetic acid which is by-product of the reaction and unreacted acetic anhydride were then removed, such that polyester amide-based liquid crystal oligomer was manufactured. Number average molecular weight of the polyester amide-based liquid crystal oligomer, which is a product, was about 4000. Composition made of the prepared liquid crystal oligomer (12 wt %), bisphenol F-based 4 functional group epoxy (8 wt %), silica (SiO₂) inorganic filler (30 wt %), and dimethylacetamide (50 wt %) was coated on each of two copper foils at a thickness of about 10 μm, such that the first RCC and the second RCC were manufactured.

### Example 1

In preparing the two RCCs manufactured by the manufacturing example, the thicknesses of the resin layers of the first RCC and the second RCC were manufactured at about 50 μm, respectively. Thereto, the first RCC, the composite having the glass fibers formed on both sides of the prepreg, and the second RCC were sequentially formed. Next, the lamination and pressurization were performed once under a lamination and pressurization condition: a lamination temperature of about 90° C., a lamination pressure of about 0.45 Mpa, and a lamination time of about 1 second. Next, the hardening was performed once under a hardening condition: a hardening temperature of about 130° C., a hardening pressure of about 2 Mpa, a hardening time of about 30 minutes, and a degree of vacuum of about 10 torr. The copper clad laminate formed by the above-mentioned method had approximately the same thickness of the resin layers based on the composite and a total of thickness of an insulating layer of the copper clad laminate was about 500 μm.

### Example 2

In preparing the two RCCs manufactured by the manufacturing example, the thickness of the resin layer of the first RCC was manufactured at about 50 μm and the thickness of the resin layer of the second RCC was manufactured at about 80 μm, respectively. Thereto, the first RCC, the insulator having the glass fiber formed on one side of the prepreg, and the composite having the glass fibers formed on both sides of the prepreg, and the second RCC were sequentially formed. Next, the lamination and pressurization were performed once under a lamination and pressurization condition: a lamination temperature of about 90° C., a lamination pressure of about 0.45 Mpa, and a lamination time of about 1 second and were repeatedly performed two times under a lamination and pressurization condition: a lamination temperature of about 90° C., a lamination pressure of about 0.48 Mpa, and a lamination time of about 0.5 second. Next, the hardening was performed under a hardening condition: a hardening temperature of about 130, a hardening pressure of about 2 Mpa, a hardening time of about 30 minutes, and a degree of vacuum of about 10 torr and was repeatedly performed two times under a hardening condition: a hardening temperature of about 230° C., a hardening pressure of about 2 Mpa, a hardening time of about 3 hours, and a degree of vacuum of about 10 torr. The copper clad laminate formed by the above-mentioned method had an asymmetric thickness of the upper and lower resin layers from the center summing the composite and the insulator and a total of thickness of an insulating layer of the copper clad laminate was about 730 μm.

According to the preferred embodiment of the present invention, the thickness of the copper clad laminate may be manufactured at the desired thickness or the thickness may be uniformly maintained, thereby making it possible to implement stabilization of thickness quality, and the adhesion between the copper foil and the resin is improved and the resin layers are formed to be symmetric or asymmetric based on the composite of the copper clad laminate, thereby making it possible to adjust warpage when laminating substrates having different upper and lower thermal expansion coefficients.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A copper clad laminate for a printed circuit board, the copper clad laminate comprising:
a composite having a glass fibers formed on both sides of a prepreg disposed between a resin layer of a first resin-coated copper foil (a first RCC) and a resin layer of a second resin-coated copper foil (a second RCC),
wherein the resin layers have a symmetric or asymmetric structure based on the composite.

2. The copper clad laminate as set forth in claim 1, wherein the resin layers of the first RCC and the second RCC have the same thickness or different thickness, the same composition or different composition, or the same kind and content or different kind and content of inorganic filler included in the composition.

3. The copper clad laminate as set forth in claim 1, wherein the composite is formed by further including at least one other prepreg between the prepreg and the glass fiber and laminating the prepreg, the at least one other prepreg, and the glass fiber.

4. The copper clad laminate as set forth in claim 1, further comprising an insulator having the glass fiber formed on one side of the prepreg between the first RCC and the composite, between the second RCC and the composite, or both.

5. The copper clad laminate as set forth in claim 4, wherein the glass fiber formed on one side of the insulator contacts the resin layers of the first RCC and the second RCC and includes at least one insulator.

6. The copper clad laminate as set forth in claim 1, wherein the glass fibers formed on both sides of the composite are the same kind or different kinds.

7. The copper clad laminate as set forth in claim 1, wherein the glass fiber is at least one selected from a group consisting of E-glass, T-glass, S-glass, U-glass, quartz fiber textile, and aramid fiber textile.

8. A manufacturing method of a copper clad laminate for a printed circuit board, the manufacturing method comprising:
providing a first RCC and a second RCC;
forming a copper clad laminate by laminating and pressurizing a composite having glass fibers formed on both sides of a prepreg between a resin layer of the first RCC and a resin layer of the second RCC; and
hardening the copper clad laminate.

9. The manufacturing method as set forth in claim 8, wherein the resin layers of the first RCC and the second RCC have the same thickness or different thickness, the same composition or different composition, or the same kind and content or different kind and content of inorganic filler included in the composition.

10. The manufacturing method as set forth in claim 8, wherein the forming of the copper clad laminating includes laminating an insulator having the glass fiber formed on one side of the prepreg between the first RCC and the composite, between the second RCC and the composite, or both.

11. The manufacturing method as set forth in claim 10, wherein the glass fiber formed on one side of the insulator is laminated so as to be in contact with the resin layers of the first RCC and the second RCC, and in the laminating of the insulator, at least one insulator is laminated.

12. The manufacturing method as set forth in claim 8, wherein the glass fibers formed on both sides of the composite are the same kind or different kinds.

13. The manufacturing method as set forth in claim 8, wherein the glass fiber is at least one selected from a group consisting of E-glass, T-glass, S-glass, U-glass, quartz fiber textile, and aramid fiber textile.

14. The manufacturing method as set forth in claim 8, wherein the pressuring is performed by roll pressurization.

15. A printed circuit board manufactured by forming a circuit pattern on a copper foil of the copper clad laminate as set forth in claim 1.
